(19) United States
(12) Patent Application Publication
(10) Pub. No.: US 2008/0303725 A1
(43) Pub. Date: Dec. 11, 2008

(54) Antenna Coupler

(75) Inventors: Wilfried Hackenbroich, Holzkirchen (DE); Barbara Schneider, Haar (DE)

Correspondence Address: PATTERSON, THUENTE, SKAAR & CHRISTENSEN, P.A., 4800 IDS CENTER, 80 SOUTH 8TH STREET, MINNEAPOLIS, MN, 55402-2100, US

(73) Assignee: WILLTEK COMMUNICATIONS GMBH, Ismaning (DE)

(21) Appl. No.: 10/580,754

(22) PCT Filed: Dec. 1, 2004
(86) PCT No.: PCT/EP2004/013641

§ 371 Date: Aug. 13, 2008

(30) Foreign Application Priority Data
Dec. 1, 2003 (DE) 103 56 087.4

(51) Int. Cl. G01R 29/08

(52) U.S. Cl. 343/703

(57) ABSTRACT

What is described is an antenna coupler for testing of wireless devices, said coupler comprising an antenna element for wireless communication with the wireless device and an accommodating element for holding the wireless device, wherein the accommodating element can be fastened in various positions relative to the antenna element by a fastening means. As an alternative or in addition, a releasable displacement of the antenna element may also be effected. In one embodiment, the fastening means is a slider, which is displaceable along the housing of the antenna coupler and carries the holder.

The invention relates to an antenna coupler for testing of wireless devices, said coupler comprising an antenna element for wireless communication with the wireless device and an accommodating element for holding the wireless device.

Such antenna coupler is described, for example, in DE 19 732 639 C1 and is used for testing wireless devices, in particular mobile or cellular phones. Antenna couplers enable full final testing of a wireless device, because also radio transmission properties of the wireless device, in particular its antenna function, can be checked. If a high-frequency interface provided on many wireless devices were resorted to instead for functional testing, the antenna would not be tested at all and antenna errors would not be detectable.

There are principally three different mechanisms for coupling with a wireless device. In inductive coupling, a coil at whose center the antenna of the wireless device is introduced is used as the coupling element. The high-frequency field of the antenna of the wireless device then couples to the coil and can thus be evaluated for further test purposes. Although inductive coupling elements achieve a very high coupling factor, their mechanical realization is difficult. In particular, it is stringently required that the coil enclose the antenna of the wireless device. Therefore, in planar antennas used increasingly in wireless devices, inductive coupling can not be used at all or only to a very limited extent, in particular if planar antennas are integrated into the housing and do not permit external access. However, inductive couplings are also confronted with concerns of measurement technology, because the small distance between the coupling coil and the wireless antenna may produce antenna detuning, including a change in the base point resistance of the wireless antenna, which then results in level distortions during measurement operation.

As an alternative to inductive coupling, capacitive couplings are known, wherein a counter-surface is opposed to a planar wireless antenna such that both surfaces form a capacitor by which high-frequency energy can be picked up from the wireless device. However, the coupling factors achieved thereby depend very much on the distance of the opposed surfaces; the coupling factor changes with the square of the distance. Therefore, high coupling factors require a very small distance between both surfaces. Moreover, apart from errors in measurement caused by variations in distance, capacitive coupling also entails the risk of influencing the function of the antenna of the wireless device such that the antenna's base point resistance is changed. Further problems of capacitive couplings arise due to reflections at the counter-surface, which may lead interference in some wireless devices.

Therefore, DE 19732639 C1 proposes an antenna coupler of the same type, wherein coupling is effected via the antenna element which is arranged close to the antenna of the wireless device and functions neither in a capacitive nor in an inductive manner. The antenna element hardly leads to interfering influences and shows, in particular, a comparatively reduced sensitivity to changes in distance. However, it is indispensable for the antenna element to be tuned to the frequency of the wireless device, as a result of which the frequency range covered by known antenna elements is smaller than the range in which the various mobile phone systems operate. Therefore, the antenna coupler described in DE 19732639 C1 comprises two planar antennas. A dipole antenna is provided for a frequency range of from 1.7 to 2.0 GHz and a slot antenna is provided for a frequency range around 0.9 GHz in order to enable testing of mobile phones for all common networks. The known antenna coupler positions the mobile phone above both antennas such that the mobile phone antenna is located at approximately the same distance from each of the two planar antennas.

As a holder for the mobile phone a universal holder is used, which clamps the mobile phone onto the antenna coupler in order to test the mobile phone. As an alternative, it is also known for antenna couplers to use special holders which are customized for specific types of wireless devices. These holders usually comprise a cradle to accommodate a mobile phone of a specific type (cf. product information for antenna coupler 4910 of Willtek Communications GmbH, Ismaning, Germany).

The technical progress in wireless devices, in particular in mobile phones and microcomputers including integrated mobile phones (so-called PDAs) is meanwhile leading to an increasing diversity of shapes with respect to the housing and the position of the wireless antenna at or in the housing. In order to achieve reproducible and, if possible, optimal positioning of the wireless device at the antenna coupler, a trend towards increased use of special holders is beginning to show. However, this has disadvantages because a multiplicity of special holders have to be kept ready and the special holders require a frequent holder change.

Therefore, it is the object of the invention to improve an antenna coupler of the type mentioned above such that optimal positioning of wireless devices can be achieved, if possible, independent of the shape of the housing and/or the antenna, with a reduced effort.

This object is achieved by an antenna coupler for testing wireless devices, which antenna coupler comprises an antenna element for wireless communication with the wireless device and an accommodating element for holding the wireless device, wherein the accommodating element comprises a fastening means by which it can releasably fastened to the antenna element in various positions.

The antenna coupler according to the invention allows simple testing of the wireless device in terms of measurement technology, in particular of a mobile phone, because said device can be wirelessly connected to a measuring device via the antenna coupler. For this purpose, the wireless device is placed in the accommodating element and held by it. As the accommodating element, any device holding the wireless device in a reproducible position can be used, in particular a universal mobile phone holder. The position of the accommodating element relative to the antenna element can be adjusted by the fastening means provided for the accommodating element. Thereby, the wireless device is reliably aligned relative to the antenna element such that optimal coupling factors between the wireless device and the antenna element are obtained. This increases precision of measurement as well as reproducibility. For the latter, an important feature of the fastening means is that the accommodating element is fastened, i.e. fixed, in a selectable position relative to the antenna element. The releaseability of this fixation allows to achieve an optimal position for the given measurement task, i.e. for a present wireless device, and thus to optimize the spatial signal propagation from the antenna of the wireless device to the antenna element.

The accommodating element ensures suitable mechanical holding of the wireless device. The shape and construction of the accommodating element ensure a reproducible position of the wireless device within the accommodating element, so that the same geometrical relationship between the antenna of the wireless device and the antenna element of the antenna coupler is always given for the same wireless device in the same position of the fastening means. Since the accommodating element is positionally adjustable relative to the antenna element via the fastening means, the optimal position of the fastening means and the accommodating element can be determined and adjusted individually for each wireless device.

The relative position between the antenna of the wireless device and the antenna element is decisive for maximum coupling factors between the wireless device and the antenna element. It is essential for the invention that the accommodating element is not fixed with respect to the antenna element in a predetermined manner, but that these two components can be fixed in different relative positions. As an alternative or in addition to the described concept comprising a positionally adjustable accommodating element a positionally adjustable antenna element can of course be used as well. The aforementioned object is therefore also achieved by an antenna coupler for testing of wireless devices, which coupler comprises an antenna element for wireless communication with the wireless device and an accommodating element for holding the wireless device, wherein the antenna element can be releaseably fastened to the accommodating element in various positions.

In such embodiment the optimal geometrical relationship between the antenna element and the wireless device is achieved by adjusting the position of the antenna element. In this variant of the invention which otherwise corresponds to the above-mentioned variant comprising the positionally adjustable accommodating element, adjustment of the accommodating element may of course be provided in addition to the adjustment of the antenna element. The realization of the positional adjustment of the antenna element may be effected in any desired manner and may adopt, in particular, the following principles described with reference to the accommodating element. Thus, where the positional adjustment of the accommodating element is referred to hereinafter, an analogous application to the adjustment of the antenna element is of course possible as well.

The positionally variable fastening of the accommodating element may be effected in different ways. For example, it is possible to provide suitable fastening means on the accommodating element, said fastening means fixing the accommodating element in a selectable position relative to the antenna coupler by the antenna element. Thus, for instance, screw fastening, in particular screw fastening in oblong holes, can also be used as well as snap closures or clamping mechanisms.

For the purpose of a compact construction of the antenna coupler it is advantageous to use a planar antenna as the antenna element. In such antenna elements, which preferably use antennas formed using stripline technology, positional adjustment between the antenna element and the accommodating element will favorably cause a parallel displacement between the accommodating element and the planar antenna, because optimal coupling can then be ensured in a simple manner.

For most cases of application, releasable fastening of the antenna element or of the accommodating element, respectively, will be sufficient if several discrete positions are provided. This is particularly easy to realize in the form of a plug-in mechanism which fastens the accommodating element to a frame or housing holding the antenna element, wherein various plug-in positions are provided according to the different locations. By simply interchanging the accommodating element or the antenna element, the relative position required for optimal coupling can thus be produced.

On the other hand, a fixing mechanism which principally enables a freely selectable displacement is provided in the form of a slider holding the accommodating element or the antenna element such that it is displaceable at least along one axis relative to the antenna element or the accommodating element, respectively. Further, a slider is an example of a realization of the antenna coupler wherein the fastening means carries the accommodating element or the antenna element, respectively. The fastening means is thus advantageously provided as a component which is interposed between the accommodating element and the antenna element, on which component the accommodating element or the antenna element is fixed, on the one hand, and which causes the desired adjustability, on the other hand.

In most cases adjustment along one axis will be sufficient when using a slider, in particular if the achievable coupling factor depends on the mutual positions of the antennas to a greater extent in one spatial direction than in another direction. This is usually the case with dipoles provided as planar antennas. However, if a spatial inhomogeneity of the high-frequency field picked up or emitted by the antenna is not present, displacement along several axes, in particular two-dimensional displacement in a plane which is parallel to the plane of the planar antenna may also appear to be particularly advantageous.

As already mentioned, a sliding mechanism, of which the above-described slider is an example, enables a principally continuous displacement. However, in order to achieve a repeatable measurement, if possible, it has turned out as favorable in everyday operation if a once used relative position between the antenna element and the accommodating element for a wireless device can be easily adjusted in a repeatable manner. For such requirements the use of a locking mechanism is advantageous which allows repeated movement to the same position in an uncomplicated manner with principally continuous positional adjustment. The locking mechanism may, for example, releasably lock the above-mentioned slider in different arrangements assigned to the different positions. The locking mechanism may release said lock in different manners. For example, lock pawls may be used, which have to be released manually in order to remove the lock. Use may also be made of suitable biasing means, in particular elastic means or springs, which allow the lock to be released upon application of a certain displacement force. Thus, for instance, the locking mechanism may use spring-biased balls engaging in suitable grooves for locking.

For the already mentioned use of a slider for the fastening means it is advantageous to provide a suitable groove on a frame or housing holding the accommodating element or the antenna element, respectively, said groove guiding the slider. This allows a particularly easy-to-manufacture and space-saving construction to be realized.

When being used with a great diversity of wireless devices, the antenna coupler will be accordingly adjusted prior to each measurement to a new type of wireless device, i.e. the corresponding relative position between the accommodating element accommodating the wireless device and the antenna element will be established. In order to be able to do so in a reproducible manner it is advantageous to provide indicating means as well as marks cooperating therewith, which indicate the arrangement of the accommodating element or of the antenna element, respectively. In the already described solution using a slider, the indicating means may be attached to the slider and the marks may be provided on the frame or housing along which the slider is guided.

Finding the optimal position is additionally facilitated by graphics provided above the antenna element which indicate a center of the antenna element at which a maximum wireless coupling effect is given. The user can then easily adjust the wireless device relative to the antenna such that the antenna of the wireless device is located above the center having the maximum coupling effect. In a dipole antenna, the center of the maximum coupling effect is located, for example, at the center of the dipole.

The invention will be explained in more detail below with reference to the drawings, wherein:

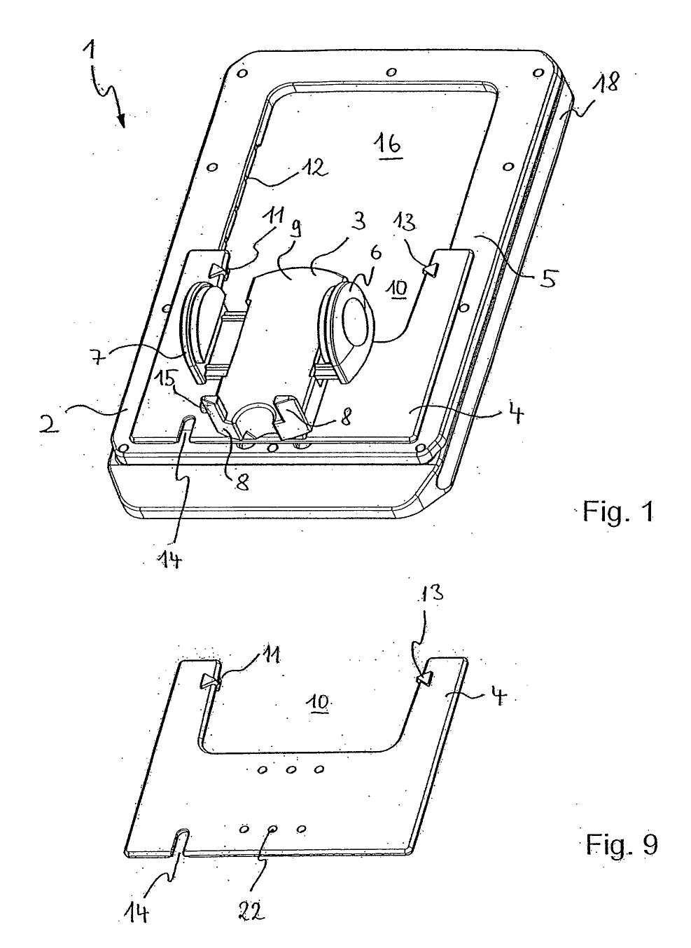

FIG. 1 shows a perspective view of an antenna coupler;

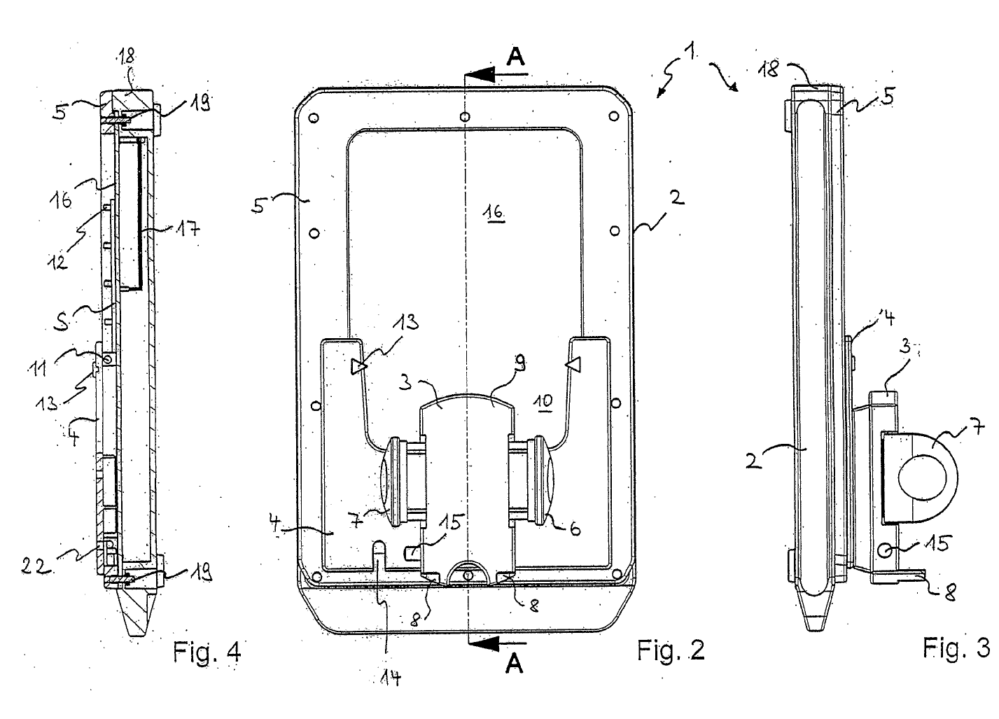

FIG. 2 shows a top view of the antenna coupler of FIG. 1;

FIG. 3 shows the antenna coupler of FIG. 1 in a left side view;

FIG. 4 shows a sectional view of the antenna coupler of FIG. 1 taken along the line A-A of FIG. 2;

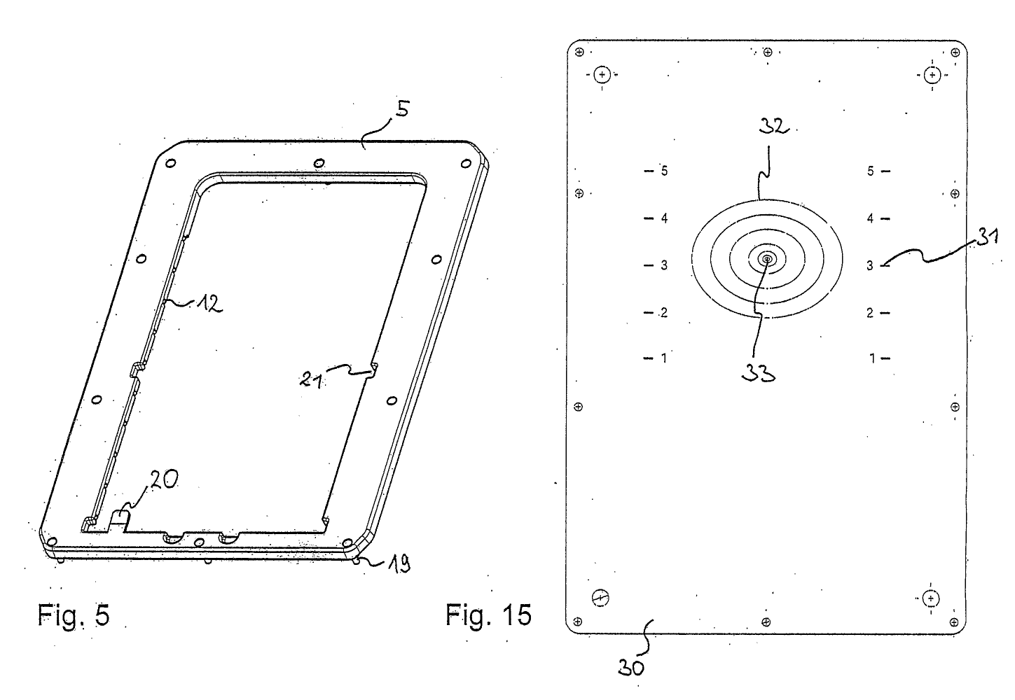

FIG. 5 shows a frame element of the antenna coupler of FIG. 1;

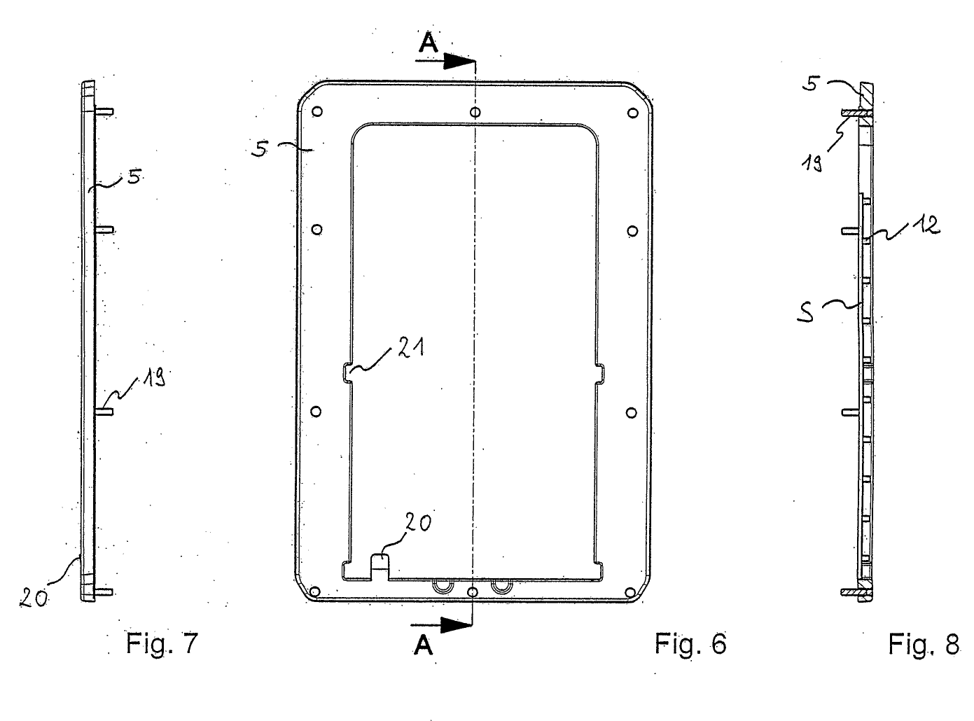

FIG. 6 shows a top view of the frame element of FIG. 5;

FIG. 7 shows a left side view of the frame element of FIG. 5;

FIG. 8 shows a sectional view of the frame element of FIG. 5 taken along the line A-A of FIG. 6;

FIG. 9 shows a perspective view of a carriage of the antenna coupler of FIG. 1;

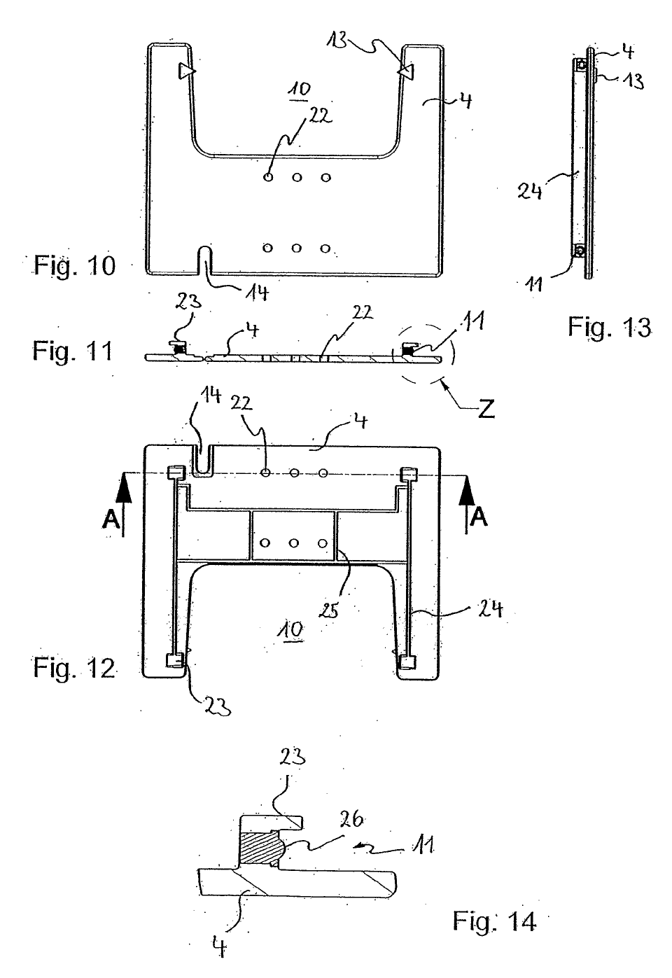

FIG. 10 shows a top view of the carriage of FIG. 9;

FIG. 11 shows a sectional view of the carriage of FIG. 10;

FIG. 12 shows the carriage of FIG. 9 from below, additionally indicating the section line along which the sectional view of FIG. 11 was obtained;

FIG. 13 shows a left side view of the carriage of FIG. 9;

FIG. 14 shows an enlarged detail of the view of FIG. 11, and

FIG. 15 shows a graphic sheet which can be attached to the antenna coupler of FIG. 1.

FIG. 1 shows a perspective view of an antenna coupler 1 which serves to wirelessly connect a wireless device (not shown) to a measurement system. The antenna coupler 1, which can also be seen in FIGS. 2, 3 and 4 in top, side and sectional views, establishes wireless communication with the wireless device and is in turn wire-connected to a measuring device (in a manner not shown).

The antenna coupler 1 comprises a housing 2 on which a holder 3 is provided which is realized, in the exemplary embodiment shown, as a universal mobile phone holder. The holder 3 is fastened to a slider 4 displacably guided along a frame 5 forming the upper side of the housing 2.

For measurement, the wireless device is placed in a holder 3 and, in the construction shown in FIG. 1, is fixed by clamping jaws 6, 7 of the holder 3. At the lower side of the holder the wireless device contacts a stop 8 such that it is securely held on a supporting surface 9 by the clamping jaws 6, 7 and the stop 8.

Depending on its design, the wireless device protrudes to a greater or lesser extent beyond the holder 3. In most wireless devices the antenna is located in this protruding region. The wireless communication is then effected between the antenna of wireless device as well as an antenna 16 which is fastened in the housing 2 below the frame 5. In the embodiments described herein the antenna of the antenna coupler is provided as a planar antenna 16 using stripline technology, as described, for example, in DE 19732639 C1, the enclosure of which is fully incorporated herein by reference.

In order to avoid interferences during wireless communication, the slider 4 comprises a recess 10 such that no or as little potentially interfering material as possible is placed between an antenna of a wireless device protruding beyond the holder 3 and the planar antenna 16 of the antenna coupler 1.

The slider 4 is provided with a locking mechanism 11, which, together with grooves 12 provided on the frame 5, locks the slider 4 in different positions. Pointers 13 attached to the slider 4 allow easy recognition of the position of the slider 4 if marks (to be described later) are provided above the planar antenna 16.

As the top view of FIG. 2 clearly shows, the slider 4 is longitudinally displaceable along the section line A-A indicated in FIG. 2. Thus, the slider 4 can be displaced along the longer inside edge of the frame 5 and so can the holder 3 attached to the slider 4. A wireless device placed on the supporting surface 9 of the holder 3 and fixed by means of the clamping jaws 6 and 7 can thus be arranged along the axis A-A in an optimal position relative to the planar antenna 16. Since the antenna 16 has a dipole characteristic in the illustrated exemplary embodiment and since the coupling factor of wireless coupling between the wireless device and the planar antenna 16 varies much more along said axis than transverse to the axis A-A, shifting along the axis A-A is sufficient here.

The universal holder 3 shown in FIG. 1 is to be construed only as an example, of course; any suitable holder can be fastened on the slider 4. In principle, any mechanism which can reproducibly fix the position of a wireless device of one or more constructions can be used as the holder 3. A button 15 is provided on the holder 3 in order to release the clamping jaws 6 and 7 holding a wireless device, said button releasing a locking mechanism provided in the holder 3 and locking the clamping jaws 6 and 7.

In order to allow removal of the slider 4 so as to change the holder, the slider 4 comprises a slot 14 in which a locking mechanism engages that shall be discussed later. By releasing the locking mechanism, the slider 4 can be pushed downwards beyond the position shown in FIG. 1 or 2, 3 and 4 and can be detached from the frame 2 by suitably provided means which are shown in FIGS. 5 and 12.

As the sectional view of FIG. 4 clearly shows, the housing 2 is formed by a bottom part 18 and by the frame 5 fixed thereon. The frame 5 is connected to the bottom part 18 by pins 19 and thus securely clamps the planar antenna 16 which is formed on a circuit board using stripline technology. An antenna feed line 17 extends within the housing towards an HF plug connector provided at the periphery of the housing 2 in a recess of the bottom part 18 (which connector is not shown in the sectional view of FIG. 4).

The frame 5 fixing the planar antenna 16 in the bottom part 18 is shown in a perspective view in FIG. 5, in a top view in FIG. 6, in a side view in FIG. 7 as well as in a sectional view taken along the line A-A of FIG. 6 in FIG. 8. Said frame is substantially rectangular and comprises, at its internal longitudinal edges, the already mentioned grooves 12 for the locking mechanism 11 of the slider 4. At its lower internal edge with respect to the representation of FIGS. 1, 5 and 6, the frame 5 has a protruding flap 20 which engages with the slot 14 upon downwards displacement of the slider 4 and thus serves as a lower stop with respect to the longitudinal displacement of the slider 4. When the flap 20, which is provided to protrude slightly upwards, is urged towards the bottom part 18, the flap 20 leaves the slot 14, and the slider 4 can be downwardly displaced a bit further so that recesses 21 provided on the internal longitudinal edges of the frame 5 allow the already mentioned removal of the slider 4 from the guide of the frame 5.

Further, the frame 5 fastened on the bottom part 18 forms a gap S, which is clearly visible in FIG. 4 and appears as a recess on the lower side of the internal longitudinal edges of the frame 5 in FIG. 8. The gap S provides the longitudinal guidance of the slider 4 in the housing 2.

As shown in FIG. 9, the slider 4 comprises several bores 22 for fastening the holder 3. In the embodiment illustrated herein the holder 3 is screwed to the slider 4 by means of screws passing through the bores 22. Of course, other fastening methods can also be used, including force-, form-, or material-locking positionally adjustable types of fastening, such as oblong holes, as well permanent types of fastening, such as adhesive bonds.

As is evident from the sectional view of FIG. 11 which shows a view taken along the line A-A of FIG. 12, the slider 4 comprises, at its lower side, four gliders 23, one pair of gliders each being located at a longitudinal internal edge of the frame 5 or in the gap S formed therein when the slider 4 is inserted. Ribbed guides 24 contacting the longitudinal internal edges of the frame 5 and improving longitudinal guidance of the slider 4 extend between each of these pairs of gliders, so as to prevent the slider from being inadvertently rotated. Stiffening ribs 25 at the lower side of the slider 4 improves stability and ensure a reproducible positional adjustment which is largely independent of the weight of the holder 3 or the weight of the wireless device.

In the side view of FIG. 13 as well as in the sectional view of FIG. 11 it is clearly recognizable that the locking mechanism 11 is provided in the region of the gliders 23, said mechanism being formed, as shown in the enlargement of the detail referred to as Z in FIG. 13, in the example of realization by spring-biased spherical protections 26, which are arranged between the lower side of the frame 4 and each glider 23 and can be locked in the notches 12.

In order to enable precise assignment of the actually set position of the holder 3 on the slider 4 relative to the housing 2 with the planar antenna 16, the front sheet 30 shown in FIG. 15 can be glued to the planar antenna 16, said sheet comprising, in addition to the index mark 31 extending along the longitudinal internal edge of the frame 5, also a central mark 32 consisting of concentric, closed curves extending around the center 33. The center 33 is the point above the planar antenna 16 at which a maximum coupling effect is to be expected when placing a wireless antenna opposite said point.

The index marks 31 allow a user to reach a position of the slider 4 in a reproducible manner. It is thus possible to provide maintenance instructions for a certain type of wireless device with the corresponding indication of the index so that wireless devices of this type are always tested in a reliable manner in the same mutual orientation of the antenna of the wireless device and the planar antenna 16. If no such indications are to be made or if they are not available, a user can find the optimal orientation of the wireless antenna relative to the center 33 of the planar antenna 16 himself by means of the central mark 32.

1-11. (canceled)

12. An antenna coupler for testing of wireless devices, said coupler comprising: an antenna element for wireless communication with the wireless device and an accommodating element for holding the wireless device, wherein the accommodating element can be adjustably fastened to the frame or housing of the antenna coupler in various positions relative to the antenna element.

13. The antenna coupler as claimed in claim 12, wherein the antenna element comprises a planar antenna.

14. The antenna coupler as claimed in claim 13 wherein the planar antenna is formed using stipline technology.

15. The antenna coupler as claimed in claim 12 wherein the accommodating element can be displaced parallel relative to the planar antenna.

16. The antenna coupler as claimed in claim 12, wherein the accommodating element is adjustably fastened to the frame or housing of the antenna coupler by a plug-in mechanism, wherein various plug-in positions are provided which correspond to the various locations on the frame or housing.

17. The antenna coupler as claimed in claim 12, wherein the accommodating element is adjustably fastened to a slider which is guided, displaceable along at least one axis, on a frame or housing holding the antenna element.

18. The antenna coupler as claimed in claim 17, further comprising a locking mechanism which releasably locks the slider in different arrangements assigned to the various positions.

19. The antenna coupler as claimed in claim 17, wherein the slider is guided in a groove provided on the frame or housing of the antenna coupler.

20. The antenna coupler as claimed in claim 12, wherein the various positions yield an at least two-dimensional relative displacement between the accommodating element and the antenna element.

21. The antenna coupler as claimed in claim 12, further comprising an indicator and cooperating marks which indicate the arrangement of the accommodating element relative to the frame or housing and/or relative to the antenna element.

22. The antenna coupler as claimed in claim 12, further comprising graphics provided above the antenna element, said graphics indicating a center of the antenna element, at which center a maximum wireless coupling effect is given.

23. The antenna coupler as claimed in claim 12, wherein the accommodating element comprises a universal mobile phone holder.

24. An antenna coupler for testing of wireless devices, said coupler comprising an antenna element for wireless communication with the wireless device and an accommodating element for holding the wireless device, wherein the antenna element can be releasably fastened to the accommodating element in various positions.

25. The antenna coupler as claimed in claim 24 wherein the antenna element comprises a planar antenna.

26. The antenna coupler as claimed in claim 25 wherein the planar antenna is formed using stipline technology.

27. The antenna coupler as claimed in claim 24 wherein the planar antenna can be displaced parallel relative to the accommodating element.

28. The antenna coupler as claimed in claim 24, wherein the antenna element is adjustably fastened to a slider which is guided, displaceable along at least one axis, on a frame or housing holding the accommodating element.

29. The antenna coupler as claimed in claim 28, further comprising a locking mechanism which releasably locks the slider in different arrangements assigned to the various positions.

30. The antenna coupler as claimed in claim 28, wherein the slider is guided in a groove provided on the frame or housing of the antenna coupler.

31. The antenna coupler as claimed in claim 24, wherein the various positions yield an at least two-dimensional relative displacement between the accommodating element and the antenna element.

32. The antenna coupler as claimed in claim 24, further comprising a pointing means and cooperating marks which indicate the arrangement of the accommodating element relative to the frame or housing and/or relative to the antenna element.

33. The antenna coupler as claimed in claim 24, further comprising graphics provided above the antenna element, said graphics indicating a center of the antenna element, at which center a maximum wireless coupling effect is given.

34. The antenna coupler as claimed in claim 24, wherein the accommodating element comprises a universal mobile phone holder.
